(19) United States
(12) Patent Application Publication
(10) Pub. No.: US 2025/0336695 A1
(43) Pub. Date: Oct. 30, 2025

(54) SUSCEPTOR FOR SUPPORTING SUBSTRATE, HEAT TREATMENT APPARATUS, AND METHOD OF MANUFACTURING SUSCEPTOR

(71) Applicant: SCREEN Holdings Co., Ltd., Kyoto (JP)

(72) Inventors: Tokuaki KUNIYOSHI, Kyoto-shi (JP); Tsukasa NISHIKAWA, Kyoto-shi (JP)

(21) Appl. No.: 19/174,897

(22) Filed: Apr. 9, 2025

(30) Foreign Application Priority Data
Apr. 25, 2024 (JP) 2024-071608

(51) Int. Cl. H01L 21/67; H01L 21/304; H01L 21/687

(52) U.S. Cl. CPC H01L 21/67115; H01L 21/3046; H01L 21/68785

(57) ABSTRACT

Halogen lamps irradiate a semiconductor wafer held by a susceptor with light from below to preheat the semiconductor wafer, and thereafter flash lamps irradiate the semiconductor wafer with flashes of light from above. A sandblasting process is performed on processing regions of a lower surface of a holding plate of the susceptor which are located between adjacent ones of a plurality of substrate support pins provided upright on the holding plate to roughen the processing regions. The processing regions are opposed to hot spots appearing when the semiconductor wafer held by the susceptor is irradiated with light. The amount of light directed toward the hot spots when the semiconductor wafer is irradiated with light from the halogen lamps is decreased by the roughened processing regions. This decreases the temperature of the hot spots to improve the uniformity of an in-plane temperature distribution of the semiconductor wafer.

### BACKGROUND

### Technical Field

The present invention relates to a susceptor which supports a substrate being heated by light irradiation, a method of manufacturing the susceptor, and a heat treatment apparatus equipped with the susceptor. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

Japanese Patent Application Laid-Open No. 2018-133424 and Japanese Patent Application Laid-Open No. 2021-77660 disclose heat treatment apparatuses employing such xenon flash lamps in which desired heat treatment is performed by combining pulsed light emitting lamps such as flash lamps disposed on a front surface side of a semiconductor wafer and continuous lighting lamps such as halogen lamps disposed on a back surface side thereof. In such heat treatment apparatuses, the semiconductor wafer is preheated to a certain degree of temperature by the halogen lamps, and the temperature of the semiconductor wafer is thereafter increased to a desired treatment temperature by pulse heating from the flash lamps. The preheating using the halogen lamps provides a process-related advantage in that the temperature of the semiconductor wafer is increased to a relatively high preheating temperature in a short time.

However, the halogen lamps arranged in two tiers, i.e. upper and lower tiers, as disclosed in Japanese Patent Application Laid-Open Nos. 2018-133424 and 2021-77660 increase the amount of light impinging on the vicinity of the center of the semiconductor wafer to give rise to a problem such that the temperature of a peripheral portion of the semiconductor wafer becomes relatively low during the preheating. To solve such a problem that a nonuniform in-plane temperature distribution occurs in the semiconductor wafer during the preheating, a cylindrically shaped louver made of opaque quartz has been used in conventional apparatuses (as disclosed in Japanese Patent Application Laid-Open No. 2018-133424).

Unfortunately, the provision of the cylindrically shaped louver eliminates the

relative temperature decrease in the peripheral portion of the semiconductor wafer, but gives rise to another problem such that the temperature of a region of the semiconductor wafer which is slightly inside the peripheral portion becomes relatively high. To solve this problem, Japanese Patent Application Laid-Open No. 2018-133424 proposes the technique of machining some regions of a susceptor which are opposed to high-temperature regions appearing in the semiconductor wafer to form low-transmission regions. In addition, Japanese Patent Application Laid-Open No. 2021-77660 discloses the technique of roughening some regions of the susceptor which are opposed to the high-temperature regions of the semiconductor wafer.

However, even with these techniques, it has been still difficult to achieve a sufficiently uniform in-plane temperature distribution of the semiconductor wafer when the semiconductor wafer is irradiated with light from the halogen lamps.

### SUMMARY

The present invention is intended for a susceptor for supporting a substrate being heated by light irradiation.

According to one aspect of the present invention, the susceptor comprises: a planar holding plate made of quartz; and a plurality of substrate support pins made of quartz and for supporting a substrate, the substrate support pins being provided upright on the holding plate, wherein the holding plate has a plurality of processing regions located between adjacent ones of the substrate support pins, and at least one or all of the processing regions have a roughened surface.

This decreases the amount of light reaching a high-temperature region of the substrate to improve the uniformity of an in-plane temperature distribution of the substrate. Preferably, the surface roughness of the roughened surface of a processing region

of the holding plate which is opposed to a region where temperature becomes relatively high is made greater than the surface roughness of the roughened surface of a processing region of the holding plate which is opposed to a region where temperature becomes relatively low in an in-plane temperature distribution occurring in the substrate when the substrate supported by the substrate support pins is irradiated with light.

This further improves the uniformity of the in-plane temperature distribution of the substrate.

The present invention is also intended for a heat treatment apparatus for irradiating a substrate with light to heat the substrate.

According to one aspect of the present invention, the heat treatment apparatus comprises: a chamber for receiving a substrate therein; the aforementioned susceptor, the susceptor being provided in the chamber and for supporting the substrate; and a continuous lighting lamp for irradiating the substrate with light from under the chamber to heat the substrate.

This improves the uniformity of the in-plane temperature distribution of the substrate.

in

The present invention is also intended for a method of manufacturing a susceptor for supporting a substrate being heated by light irradiation.

According to one aspect of the present invention, the method comprises the step of performing a roughening process on at least one or all of a plurality of processing regions of a planar holding plate which are located between adjacent ones of a plurality of substrate support pins provided upright on the holding plate, the holding plate being made of quartz.

This decreases the amount of light reaching the high-temperature region of the substrate to improve the uniformity of the in-plane temperature distribution of the substrate.

Preferably, the grain size of an abrasive for the sandblasting process to be performed on a processing region of the holding plate which is opposed to a region where temperature becomes relatively high is made smaller than the grain size of an abrasive for the sandblasting process to be performed on a processing region of the holding plate which is opposed to a region where temperature becomes relatively low in a temperature distribution occurring in the substrate when the substrate supported by the substrate support pins is irradiated with light.

This further improves the uniformity of the in-plane temperature distribution of the substrate.

It is therefore an object of the present invention to improve the uniformity of an in-plane temperature distribution of a substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a view showing an example of a temperature distribution occurring in a wafer surface when a semiconductor wafer held by the susceptor which is not especially processed is irradiated with light from the halogen lamps;

FIG. 9 is a plan view of a holding plate as seen from below;

FIG. 10 is an enlarged view of a single processing region and its vicinity; and

FIGS. 11 and 12 are views showing other examples of the shape of the processing region.

### DESCRIPTION OF THE PREFERRED EMBODIMENTS

A preferred embodiment according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

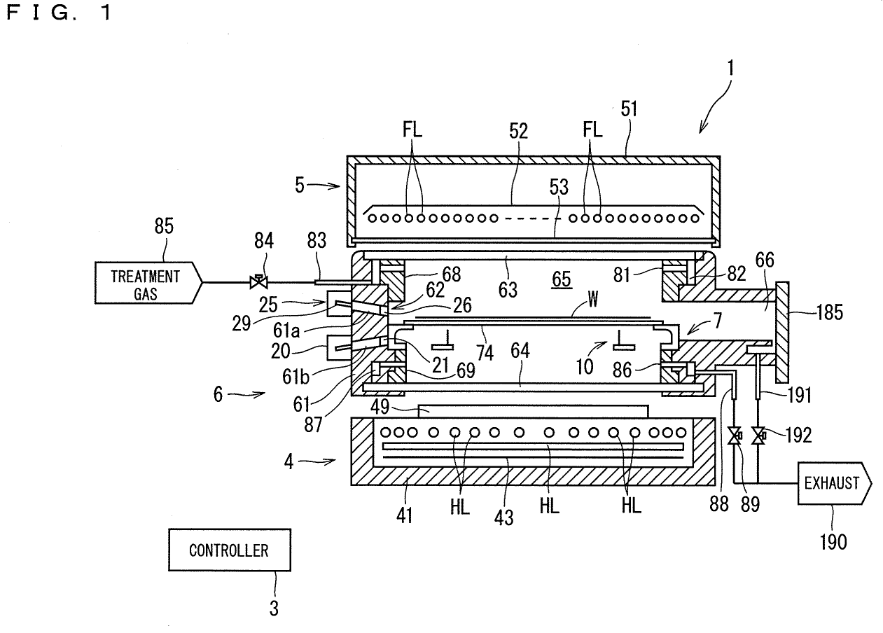

FIG. 1 is a longitudinal sectional view showing a configuration of a heat treatment

apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm (in the present preferred embodiment, 300 mm). It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a and a through hole 61b both bored therein. The through hole 61a is a cylindrical hole for directing infrared light emitted from an upper surface of a semiconductor wafer W held by a susceptor 74 to be described later therethrough to an infrared sensor 29 of an upper radiation thermometer 25. The through hole 61b is a cylindrical hole for directing infrared light emitted from a lower surface of the semiconductor wafer W therethrough to a lower radiation thermometer 20. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect main surfaces of the semiconductor wafer

W held by the susceptor 74. A transparent window 26 made of calcium fluoride material transparent to infrared light in a wavelength range measurable with the upper radiation thermometer 25 is mounted to an end portion of the through hole 61a which faces the heat treatment space 65. A transparent window 21 made of barium fluoride material transparent to infrared light in a wavelength range measurable with the lower radiation thermometer 20 is mounted to an end portion of the through hole 61b which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

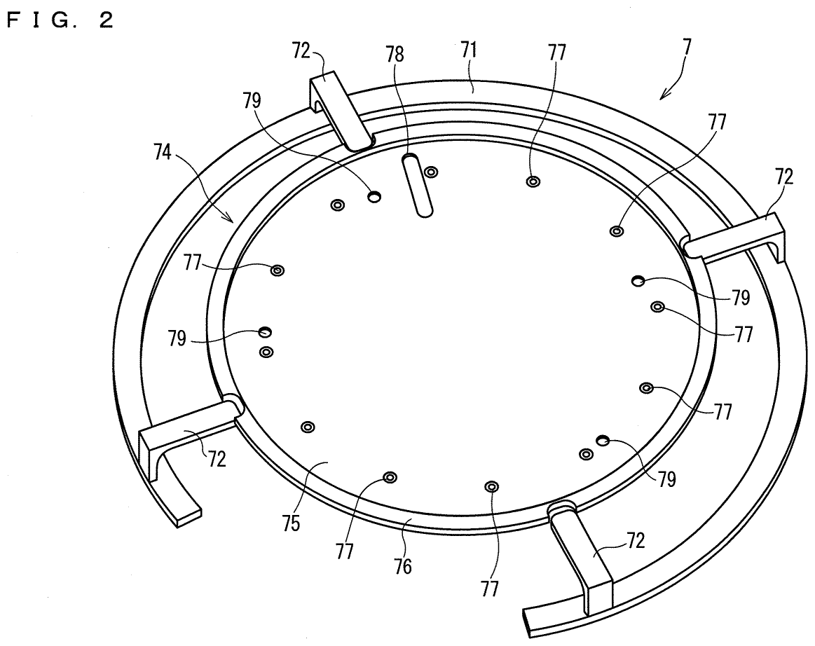

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

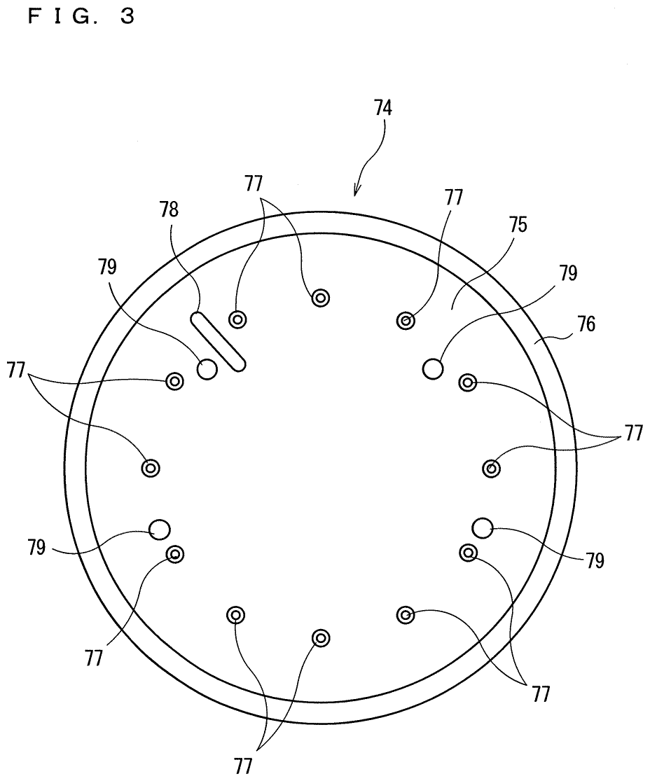

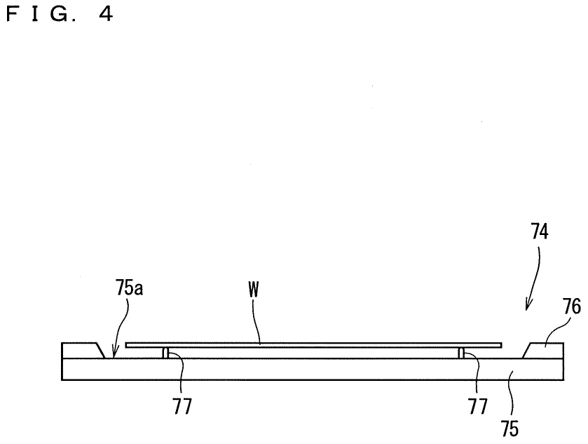

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77.

Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the lower radiation thermometer 20 to receive radiation (infrared light) emitted from the lower surface of the semiconductor wafer W. Specifically, the lower radiation thermometer 20 receives the radiation emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W. In the present preferred embodiment, a roughening process is applied to some regions of a lower surface of the holding plate 75 of the susceptor 74 to decrease the transmittance thereof, which will be described further later.

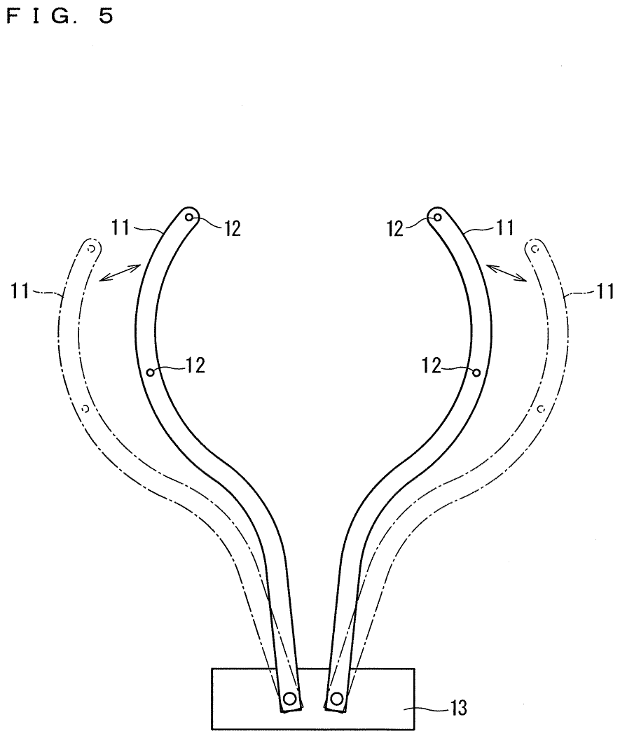

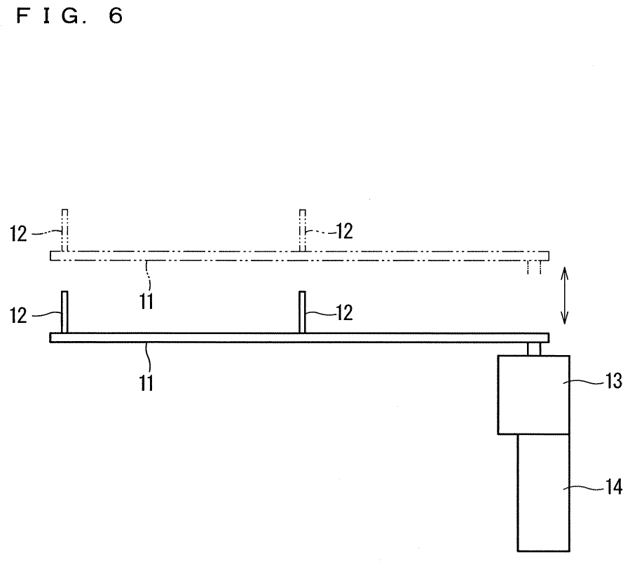

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 is a light irradiator that directs light from under the chamber 6 through the lower chamber window 64 toward the heat treatment space 65 to heat the semiconductor wafer W by means of the halogen lamps HL.

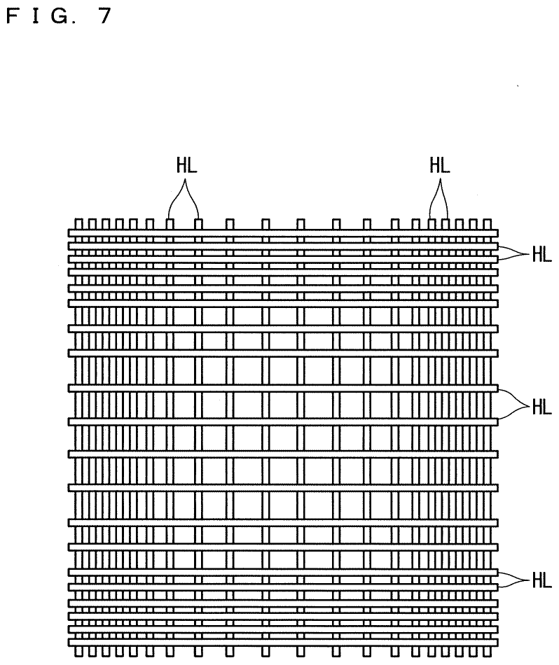

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second.

In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

A louver 49 is provided between the halogen heating part 4 and the lower chamber window 64 of the chamber 6 (with reference to FIG. 1). The louver 49 is a cylindrically shaped (cylindrically shaped with no bottom) member having open top and bottom ends. The louver 49 is made of a material opaque to the light emitted from the halogen lamps HL of the halogen heating part 4, and is made of opaque quartz which is, for example, quartz glass containing a multiplicity of microscopic air bubbles. The size of the louver 49 may be adjusted as appropriate in accordance with the layouts of the chamber 6 and the halogen heating part 4. The outer diameter of the cylinder of the louver 49 is required only to be smaller than a region in which the halogen lamps HL are arranged. For example, the louver 49 has an outer diameter of 300 mm which is equal to the diameter of the semiconductor wafer W, and an inner diameter of 294 mm. The louver 49 may have a height of 15 to 25 mm, for example. The central axis of the cylindrically shaped louver 49 passes through the center of the semiconductor wafer W held by the susceptor 74.

As shown in FIG. 1, the heat treatment apparatus 1 includes the upper radiation thermometer 25 and the lower radiation thermometer 20. The upper radiation thermometer 25 is provided obliquely above the semiconductor wafer W held by the susceptor 74, and receives the infrared radiation emitted from the upper surface of the semiconductor wafer W to measure the temperature of the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of flash irradiation. On the other hand, the lower radiation thermometer 20 is provided obliquely below the semiconductor wafer W held by the susceptor 74, and receives the infrared radiation emitted from the lower surface of the semiconductor wafer W to measure the temperature of the lower surface of the semiconductor wafer W.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like thereon. The CPU in the controller 3 executes a predetermined processing program, whereby the processes in the heat treatment apparatus 1 proceed.

In the present preferred embodiment, the roughening process is performed on part of the holding plate 75 of the susceptor 74. Specifically, a sandblasting process is performed on processing regions of the lower surface of the holding plate 75 which are located between adjacent ones of the substrate support pins 77 to roughen the processing regions.

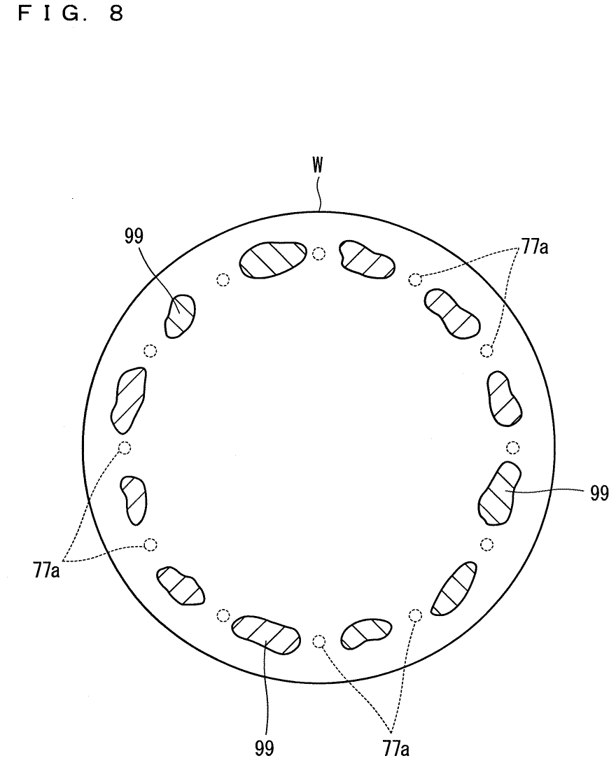

FIG. 8 is a view showing an example of a temperature distribution occurring in a wafer surface when the semiconductor wafer W held by the susceptor 74 which is not especially processed is irradiated with light from the halogen lamps HL. When the 40 halogen lamps HL are arranged in two tiers, i.e. upper and lower tiers, as in the present preferred embodiment, the amount of light impinging from the halogen heating part 4 upon the vicinity of the center of the semiconductor wafer W is relatively large.

To prevent this, the louver 49 is provided between the halogen lamps HL of the halogen heating part 4 and the susceptor 74 of the holder 7 in the present preferred embodiment. When the multiple halogen lamps HL emit light, the light directed from the halogen lamps HL provided outside the louver 49 toward the vicinity of a central portion of the semiconductor wafer W is blocked by a wall surface of the opaque louver 49. On the other hand, the light directed from the halogen lamps HL provided outside the louver 49 toward the peripheral portion of the semiconductor wafer W is not blocked. In other words, the provision of the louver 49 hardly decreases the light directed from the halogen lamps HL toward the peripheral portion of the semiconductor wafer W, but decreases the light directed from the halogen lamps HL toward the vicinity of the center of the semiconductor wafer W. As a result, the heating of the vicinity of the center of the semiconductor wafer W where hot spots are prone to result is weakened, whereas the peripheral portion of the semiconductor wafer W where a temperature decrease is prone to occur is heated relatively strongly.

However, if the louver 49 is simply provided over the halogen heating part 4, there are cases in which regions slightly inside the peripheral portion of the semiconductor wafer W become hot spots when the semiconductor wafer W is heated by light irradiation from the halogen lamps HL. A hot spot refers to a region which is relatively higher in temperature than other regions in the surface of the semiconductor wafer W.

As mentioned above, the 12 substrate support pins 77 having a diameter of 270 to 280 mm and equally spaced along the same circumference are provided upright on the holding plate 75 of the susceptor 74. The semiconductor wafer W is supported by these 12 substrate support pins 77. The provision of the louver 49 causes the amount of light impinging upon the vicinity of the circle (referred to hereinafter as a “pin arrangement circle” in some cases) on which the 12 substrate support pins 77 are provided in the surface of the semiconductor wafer W to become relatively large, whereby that region is at a high temperature. However, locations in direct contact with the substrate support pins 77 are less prone to be at high temperature because of heat conduction to the substrate support pins 77. As a result, when the semiconductor wafer W is irradiated with light from the 40 halogen lamps HL, hot spots 99 appear in a region of the surface of the semiconductor wafer W which extends along the circumference of the pin arrangement circle except contact locations 77a with the substrate support pins 77, as shown in FIG. 8. The present inventors have identified the in-plane temperature distribution shown in FIG. 8 in advance through experiments using the susceptor 74 which is not especially processed or simulations.

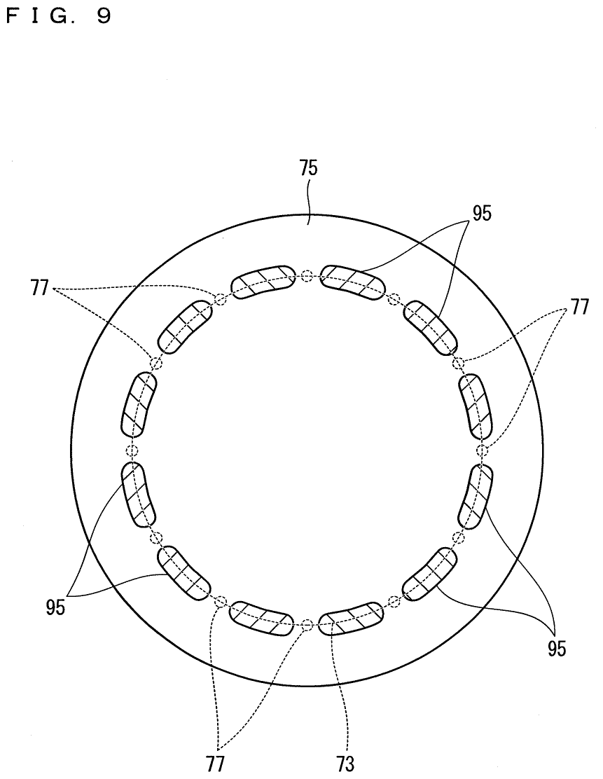

Based on the nonuniformity of the in-plane temperature distribution shown in FIG. 8, the present preferred embodiment performs the sandblasting process on the processing regions of the lower surface of the holding plate 75 which are located between adjacent ones of the substrate support pins 77 to roughen the processing regions, thereby decreasing the transmittance thereof. FIG. 9 is a plan view of the holding plate 75 as seen from below. Twelve processing regions 95 present between adjacent ones of the 12 substrate support pins 77 equally spaced (at intervals of 30 degrees) along the circumference of a pin arrangement circle 73 are roughened. The 12 processing regions 95 are also provided along the circumference of the pin arrangement circle 73. These processing regions 95 are opposed to the hot spots 99 appearing in the semiconductor wafer W held by the susceptor 74.

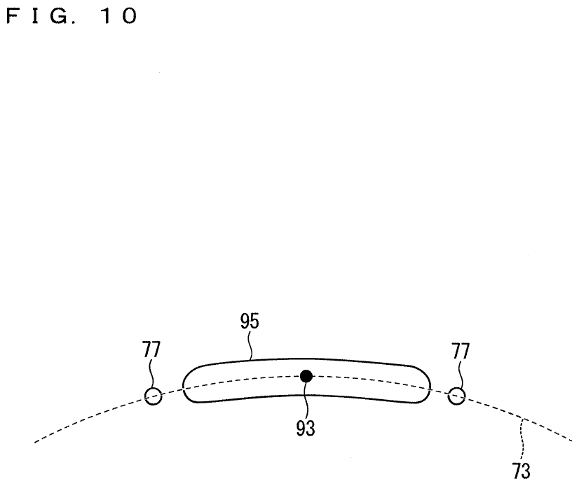

FIG. 10 is an enlarged view of one of the processing regions 95 and its vicinity. Each of the processing regions 95 located between adjacent ones of the substrate support pins 77 has an oval shape. The oval shape is a shape which broadly includes rounded, horizontally long curves, and is composed of differentiable (smooth) curves. The oval shape is also composed of protruding closed curves that do not intersect. The oval shape includes oblong shapes (elliptical shapes), elongated hole shapes, egg shapes, and the like. More specifically, the processing regions 95 of the present preferred embodiment have the shape of a substantially elongated hole along the circumference of the pin arrangement circle 73. Two curves extending in a longitudinal direction of each of the processing regions 95 are arcs of circles concentric with the pin arrangement circle 73. The processing regions 95 have a width (a dimension as measured in a radial direction of the pin arrangement circle 73) of 15 mm, for example. The processing regions 95 have a length (a dimension as measured in a circumferential direction of the pin arrangement circle 73) which is a value covering, for example, 20 degrees of the pin arrangement circle 73.

The position of the center of gravity 93 of the oval shape of a processing region 95 coincides with the midpoint between adjacent ones of the substrate support pins 77 which are on either side of the processing region 95 along the circumference of the pin arrangement circle 73. When adjacent ones of the substrate support pins 77 are spaced at intervals of 30 degrees as in the present preferred embodiment, the position of the center of gravity 93 is 15 degrees away from both the adjacent substrate support pins 77 along the circumference of the pin arrangement circle 73.

The 12 processing regions 95 are roughened by the sandblasting process. The sandblasting process is a processing method in which compressed air mixed with an abrasive (sand) is blown onto a target. The grain size of the abrasive used for the sandblasting process is between #240 and #800 (#600 in the present preferred embodiment) in accordance with JIS (Japanese Industrial Standards). The smaller the grain size (grit size), the coarser the abrasive (the greater the average grain diameter). Thus, as the grit size decreases, the surface roughness of the processing regions 95 after the process increases (becomes coarser), and the transmittance thereof decreases.

If the grain size of the abrasive used for the sandblasting process is less than #240, the surface roughness of the processing regions 95 after the process becomes excessively large, and the transmittance of the processing regions 95 decreases significantly. In this case, locations of the surface of the semiconductor wafer W which are opposed to the processing regions 95 are shadowed by the processing regions 95 when the semiconductor wafer W is irradiated with light from the halogen lamps HL, and there is apprehension that these locations become cold spots because the light hardly reaches the locations. On the other hand, if the grain size of the abrasive used for the sandblasting process is greater than #800, the surface roughness of the processing regions 95 after the process becomes excessively small, and the processing regions 95 have a nearly smooth surface, rather than a roughened surface. In this case, the transmittance of the processing regions 95 does not decrease, and the effect of decreasing the light using the processing regions 95 is hardly obtained. For these reasons, the grain size of the abrasive used for the sandblasting process is between #240 and #800.

When the sandblasting process is performed on the processing regions 95 using an abrasive having a grain size of #240, the surface roughness (arithmetic mean roughness (Ra)) of the processing regions 95 is 2.0 μm. On the other hand, when the sandblasting process is performed on the processing regions 95 using an abrasive having a grain size of #800, the surface roughness of the processing regions 95 is 0.2 μm. That is, when the grain size of the abrasive used for the sandblasting process is between #240 and #800, the surface roughness of the processing regions 95 after the process is between 0.2 and 2.0 μm.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a treatment operation in the heat treatment apparatus 1 will be described. A typical heat treatment operation for an ordinary semiconductor wafer (product wafer) W that becomes a product will be described. A procedure for the treatment of the semiconductor wafer W which will be described below proceeds under the control of the controller 3 over the operating mechanisms of the heat treatment apparatus 1.

First, the valve 84 for supply of gas is opened, and the valves 89 and 192 for exhaust of gas are opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports the semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof that is patterned is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heating part 4 turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

In the present preferred embodiment, the processing regions 95 of the lower surface of the holding plate 75 which are located between adjacent ones of the substrate support pins 77 are roughened by the sandblasting process. Thus, the transmittance of the processing regions 95 is lower than that of other regions. This decreases the amount of light impinging on the hot spots 99 of the semiconductor wafer W which are opposed to the processing regions 95 to decrease the temperature of the hot spots 99. As a result, the uniformity of the in-plane temperature distribution of the semiconductor wafer W is improved when the semiconductor wafer W is irradiated with light from the halogen lamps HL.

The temperature of the semiconductor wafer W is measured by the lower radiation thermometer 20 when the halogen lamps HL perform the preheating. Specifically, the lower radiation thermometer 20 receives infrared radiation emitted from the lower surface of the semiconductor wafer W held by the susceptor 74 through the opening 78 and passing through the transparent window 21 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the lower radiation thermometer 20. In this manner, the lower radiation thermometer 20 is a radiation thermometer for controlling the temperature of the semiconductor wafer W during the preheating.

After the temperature of the semiconductor wafer W reaches the preheating temperature T1, the controller 3 maintains the temperature of the semiconductor wafer W at the preheating temperature T1 for a short time. Specifically, when the temperature of the semiconductor wafer W measured by the lower radiation thermometer 20 reaches the preheating temperature T1, the controller 3 adjusts the output from the halogen lamps HL to maintain the temperature of the semiconductor wafer W at approximately the preheating temperature T1.

The flash lamps FL in the flash heating part 5 irradiate the front surface of the semiconductor wafer W held by the susceptor 74 with a flash of light when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2, and thereafter decreases rapidly.

After a predetermined time period has elapsed since the completion of the flash heating treatment, the halogen lamps HL turn off. This causes the temperature of the semiconductor wafer W to decrease rapidly from the preheating temperature T1. The lower radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the lower radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

In the present preferred embodiment, the sandblasting process is performed on the processing regions 95 of the lower surface of the holding plate 75 which are located between adjacent ones of the substrate support pins 77 provided upright on the holding plate 75 to roughen the processing regions 95, thereby decreasing the transmittance thereof.

The processing regions 95 are opposed to the hot spots 99 appearing in the semiconductor wafer W held by the susceptor 74. Thus, the amount of light directed from the halogen lamps HL toward the hot spots 99 during the preheating is decreased by the processing regions 95 which are roughened. As a result, the temperature of the hot spots 99 is decreased, whereby the uniformity of the in-plane temperature distribution of the semiconductor wafer W is improved during the preheating. This improves the yield of semiconductor wafers W, and suppresses the cracking of the semiconductor wafers W due to the nonuniformity of the temperature distribution.

While the preferred embodiment according to the present invention has been described hereinabove, various modifications of the present invention in addition to those described above may be made without departing from the scope and spirit of the invention.

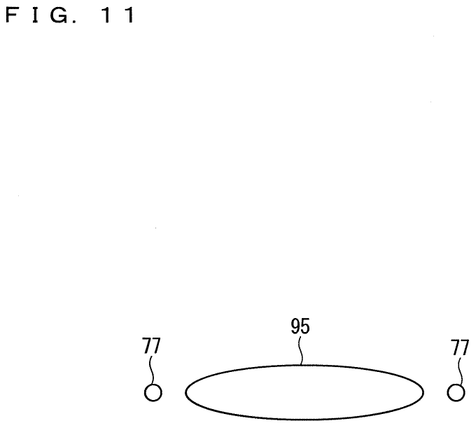

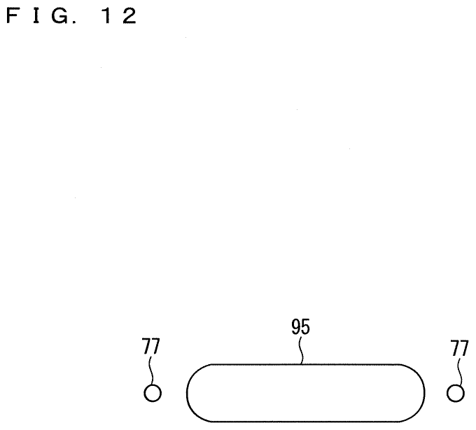

For example, the shape of the processing regions 95 is the substantially elongated hole shape along the circumference of the pin arrangement circle 73 in the aforementioned preferred embodiment, but is not limited to this. The shape of the processing regions 95 may be a shape as shown in FIG. 11 or 12, for example. FIGS. 11 and 12 are views showing other examples of the shape of the processing regions 95. The processing region 95 shown in FIG. 11 has an oblong shape (elliptical shape). The processing region 95 shown in FIG. 12 has an elongated hole shape having two parallel straight lines extending in a longitudinal direction. Even with either shape, the processing regions 95 are located between adjacent ones of the substrate support pins 77 to produce effects similar to those of the aforementioned preferred embodiment. Alternatively, the processing regions 95 may be truly circular or rectangular in shape.

In the aforementioned preferred embodiment, the surface roughness of the processing regions 95 after the process is between 0.2 and 2.0 μm. However, the processing regions 95 may have respective different surface roughness values within this range. Specifically, the surface roughness of a processing region 95 opposed to a region where temperature becomes relatively high is made greater than the surface roughness of a processing region 95 opposed to a region where temperature becomes relatively low in the in-plane temperature distribution (for example, the temperature distribution shown in FIG. 8) occurring in the semiconductor wafer W when the semiconductor wafer W supported by the substrate support pins 77 is irradiated with light from the halogen lamps HL. In other words, the grain size of the abrasive for the sandblasting process to be performed on the processing region 95 opposed to the region where temperature becomes relatively high is made smaller than the grain size of the abrasive for the sandblasting process to be performed on the processing region 95 opposed to the region where temperature becomes relatively low in the in-plane temperature distribution occurring in the semiconductor wafer W. This significantly decreases the amount of light directed toward the region where temperature becomes higher in the in-plane temperature distribution occurring in the semiconductor wafer W to further improve the uniformity of the in-plane temperature distribution of the semiconductor wafer W.

In the aforementioned preferred embodiment, the sandblasting process is performed on all of the 12 processing regions 95 present between adjacent ones of the 12 substrate support pins 77. The present invention, however, is not limited to this. Only some of the processing regions 95 may be roughened. For example, only a processing region 95 opposed to a hot spot 99 which is at a temperature higher than that of its surroundings by a certain threshold value may be roughened by the sandblasting process.

In the aforementioned preferred embodiment, the sandblasting process is performed as a technique for roughening the processing regions 95. The present invention, however, is not limited to this. Other chemical or physical techniques may be employed. For example, the processing regions 95 may be roughened by etching using a predetermined chemical liquid. Alternatively, the processing regions 95 may be roughened by grinding.

The louver 49 is provided to adjust an illuminance distribution in the aforementioned preferred embodiment, but is not an essential element. Alternatively, other illuminance adjustment members such as a planar member made of opaque quartz may be provided in place of or in addition to the louver 49.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiment, the filament-type halogen lamps HL are used as continuous lighting lamps that emit light continuously for not less than one second to perform the preheating of the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A susceptor for supporting a substrate being heated by light irradiation, comprising:
a planar holding plate made of quartz; and
a plurality of substrate support pins made of quartz and for supporting a substrate, said substrate support pins being provided upright on said holding plate,
wherein said holding plate has a plurality of processing regions located between adjacent ones of said substrate support pins, and at least one or all of said processing regions have a roughened surface.

2. The susceptor according to claim 1,
wherein said substrate support pins are equally spaced on the same circumference, and
wherein said processing regions are provided along said circumference.

3. The susceptor according to claim 2,
wherein each of said processing regions has an oval shape.

4. The susceptor according to claim 3,
wherein the center of gravity of said oval shape coincides with a midpoint between adjacent ones of said substrate support pins which are on either side of a processing region of said oval shape along said circumference.

5. The susceptor according to claim 2,
wherein each of said processing regions has an oblong shape or an elongated hole shape.

6. The susceptor according to claim 1,
wherein said roughened surface has a surface roughness between 0.2 and 2.0 μm.

7. The susceptor according to claim 6,
wherein the surface roughness of the roughened surface of a processing region of said holding plate which is opposed to a region where temperature becomes relatively high is made greater than the surface roughness of the roughened surface of a processing region of said holding plate which is opposed to a region where temperature becomes relatively low in an in-plane temperature distribution occurring in said substrate when said substrate supported by said substrate support pins is irradiated with light.

8. A heat treatment apparatus for irradiating a substrate with light to heat the substrate, comprising:
a chamber for receiving a substrate therein;
a susceptor as recited in claim 1, said susceptor being provided in said chamber and for supporting said substrate; and
a continuous lighting lamp for irradiating said substrate with light from under said chamber to heat said substrate.

9. The heat treatment apparatus according to claim 8, further comprising
a light blocking member disposed between said susceptor and said continuous lighting lamp.

10. The heat treatment apparatus according to claim 8, further comprising
a flash lamp for irradiating said substrate with a flash of light from over said chamber.

11. A method of manufacturing a susceptor for supporting a substrate being heated by light irradiation, comprising the step of
performing a roughening process on at least one or all of a plurality of processing regions of a planar holding plate which are located between adjacent ones of a plurality of substrate support pins provided upright on said holding plate, said holding plate being made of quartz.

12. The method according to claim 11,
wherein said substrate support pins are equally spaced on the same circumference, and
wherein said processing regions are provided along said circumference.

13. The method according to claim 12,
wherein each of said processing regions has an oval shape.

14. The method according to claim 13,
wherein the center of gravity of said oval shape coincides with a midpoint between adjacent ones of said substrate support pins which are on either side of a processing region of said oval shape along said circumference.

15. The method according to claim 12,
wherein each of said processing regions has an oblong shape or an elongated hole shape.

16. The method according to claim 11,
wherein said roughening process is a sandblasting process.

17. The method according to claim 16,
wherein the grain size of an abrasive used for said sandblasting process is between #240 and #800.

18. The method according to claim 17,
wherein the grain size of an abrasive for said sandblasting process to be performed on a processing region of said holding plate which is opposed to a region where temperature becomes relatively high is made smaller than the grain size of an abrasive for said sandblasting process to be performed on a processing region of said holding plate which is opposed to a region where temperature becomes relatively low in a temperature distribution occurring in said substrate when said substrate supported by said substrate support pins is irradiated with light.
